(19) United States
(12) Patent Application Publication
(10) Pub. No.: US 2010/0248487 A1
(43) Pub. Date: Sep. 30, 2010

(54) METHOD AND APPARATUS FOR ELIMINATION OF MICRO-TRENCHING DURING ETCHING OF A HARDMASK LAYER

(76) Inventors: Gene H. Lee, San Jose, CA (US); Wallace Wang, Hsinchu (TW); Bei Hao, Xian (CN)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/716,985

(22) Filed: Mar. 3, 2010

Related U.S. Application Data
(60) Provisional application No. 61/157,013, filed on Mar. 3, 2009.

(51) Int. Cl. H01L 21/306

(52) U.S. Cl. 438/706; 257/E21.219

(57) ABSTRACT

Described herein are exemplary methods and apparatuses for etching a nitride layer disposed above a substrate to form trenches without micro-trenching in accordance with one embodiment. The method includes forming openings in a resist layer and one or more dielectric layers. The dielectric layers may be disposed on a hard mask layer (e.g., nitride, polysilicon). Next, the method includes etching openings in the hard mask layer disposed above a substrate layer without micro-trenching. The etching occurs in a process chamber during a main etch with a first process gas mixture having a fluorocarbon gas, a hydrofluorocarbon gas, and an oxygenating gas. Next, the method includes etching openings partially into the substrate without micro-trenching with a second process gas mixture during an over etch having the fluorocarbon gas, the hydrofluorocarbon gas, and the oxygenating gas.

### RELATED APPLICATIONS

This application claims the benefit of U.S. Provisional Application No. 61/157,013, filed Mar. 3, 2009, which is hereby incorporated by reference.

### TECHNICAL FIELD

Embodiments of the present invention relate to eliminating micro-trenching during plasma etching.

### BACKGROUND

For advanced semiconductor processing, it is important to achieve very good critical dimension (CD) uniformity across a substrate or wafer, especially along a wafer edge when etching a Nitride layer. For example, shallow trench isolation (STI) typically requires a nitride layer hard mask prior to etching into a silicon substrate to form trenches. These trenches will be deposited with an insulator to provide isolation between devices.

In order to achieve very good CD uniformity, it is necessary to operate at low process regimes. However, at this process regime, there is a tendency to micro-trench into a silicon substrate layer that is below the nitride layer during the etching of the nitride layer as illustrated in FIG. 1. Micro-trenching etches the perimeter of the feature near a sidewall at a faster etch rate than etching occurs within the feature at a greater distance from the sidewall. The periphery of a substrate or wafer may be more sensitive to the micro-trenching because of various process effects. One potential cause of micro-trenching is ion deflection of a sidewall of the nitride layer. Micro-trenching is typically more severe in a periphery of an open feature and isolated features. Another potential cause is an interaction of local electric field induced ion charging, selectivity to an underlying layer, and a mean-free path of ion bombardment. The micro-trenching will then transfer into the silicon substrate while etching the silicon substrate to form the silicon trenches as illustrated in FIGS. 2A and 2B. Device reliability and yield will be compromised as a result of the micro-trenching during the STI processing.

### SUMMARY

Described herein are exemplary methods and apparatuses for etching a nitride layer disposed above a substrate to form trenches without micro-trenching in accordance with one embodiment. The method includes forming openings in a resist layer and one or more dielectric layers. The dielectric layers may be disposed on a hard mask layer (e.g., nitride, polysilicon). Next, the method includes etching openings in the hard mask layer disposed above a substrate layer without micro-trenching. The etching occurs in a process chamber during a main etch with a first process gas mixture having a fluorocarbon gas, a hydrofluorocarbon gas, and an oxygenating gas. Next, the method includes etching openings partially into the substrate without micro-trenching with a second process gas mixture during an over etch having the fluorocarbon gas, the hydrofluorocarbon gas, and the oxygenating gas.

### BRIEF DESCRIPTION OF THE DRAWINGS

Embodiments of the present invention are illustrated by way of example, and not by way of limitation, in the figures of the accompanying drawings and in which:

FIG. 1 illustrates a nitride layer being etched above a silicon layer and the resulting micro-trenching;

FIG. 2A illustrates a nitride layer being etched above a silicon layer and the resulting micro-trenching;

FIG. 2B illustrates a silicon layer being etched with the micro-trenching being transferred into a silicon trench being etched;

FIG. 3 illustrates one embodiment of a method for etching a masking layer disposed above a substrate to form trenches without micro-trenching in accordance with one embodiment;

FIG. 4A illustrates a cross-sectional view of a structure fabricated to form trenches without micro-trenching in accordance with one embodiment;

FIG. 4B illustrates a cross-sectional view of a structure fabricated to form trenches without micro-trenching in accordance with another embodiment;

FIG. 4C illustrates a cross-sectional view of a structure fabricated to form trenches without micro-trenching in accordance with another embodiment;

FIG. 4D illustrates a cross-sectional view of a structure fabricated to form trenches without micro-trenching in accordance with one embodiment;

FIG. 4E illustrates a cross-sectional view of a structure fabricated to form trenches without micro-trenching in accordance with another embodiment;

FIGS. 5A and 5B illustrate cross-sectional views of a structure fabricated to form trenches without micro-trenching in accordance with one embodiment;

FIGS. 6A and 6B illustrate cross-sectional views of a structure fabricated to form trenches in accordance with another embodiment;

FIGS. 7A and 7B illustrate cross-sectional views of a structure fabricated to form trenches without micro-trenching in accordance with another embodiment;

FIGS. 8A and 8B illustrate cross-sectional views of a structure fabricated to form trenches without micro-trenching in accordance with another embodiment;

FIG. 9 illustrates a cross-sectional view of a structure fabricated to form trenches having micro-trenching in accordance with a conventional approach;

FIG. 10 illustrates a cross-sectional view of a structure fabricated to form trenches without micro-trenching in accordance with another embodiment;

FIGS. 11 and 12 illustrate uniformity maps of a nitride layer after the nitride layer is etched in accordance with one embodiment;

FIG. 13 is a substrate processing tool in accordance with one embodiment;

FIG. 14A illustrates a center to edge etch rate uniformity diagram for the substrate processing tool in accordance with one embodiment;

FIG. 14B illustrates a center to edge CD uniformity diagram for the substrate processing tool in accordance with one embodiment;

FIG. 14C illustrates a wafer temperature tunability diagram for the substrate processing tool in accordance with one embodiment;

FIG. 15 is a substrate processing tool in accordance with another embodiment;

FIG. 16 illustrates flow diagrams for a reactant mass fraction control of the substrate processing tool in accordance with one embodiment; and

FIG. 17 illustrates product flux diagrams for center versus edge flow of the substrate processing tool in accordance with one embodiment.

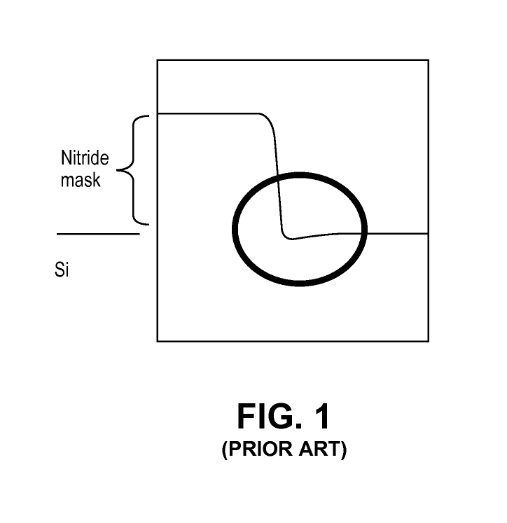

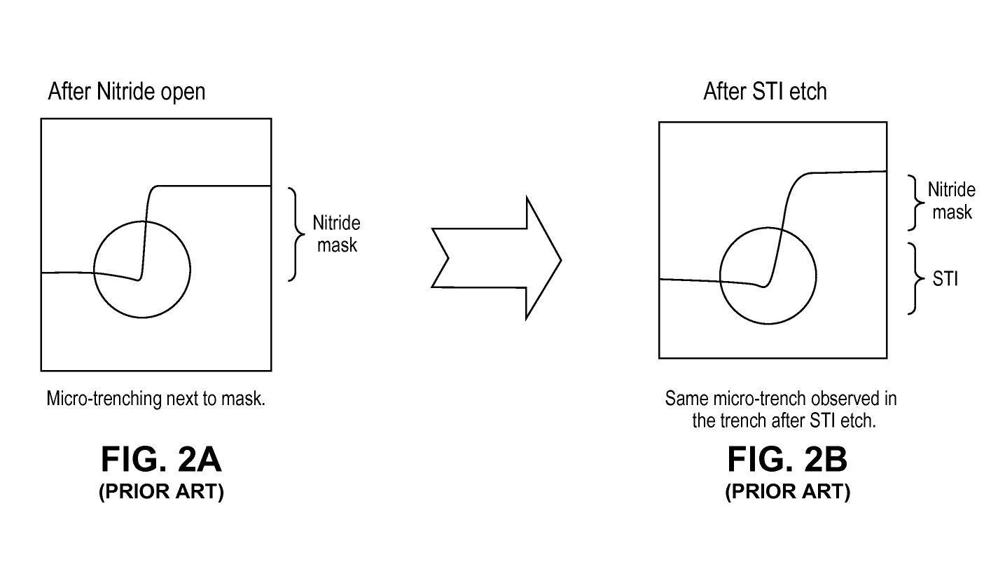

### DETAILED DESCRIPTION

Described herein are exemplary methods and apparatuses for etching a nitride layer disposed above a substrate to form trenches without micro-trenching in accordance with one embodiment. The method includes forming openings in a resist layer and one or more dielectric layers. The dielectric layers may be disposed on a hard mask layer (e.g., nitride, polysilicon). Next, the method includes etching openings in the hard mask layer disposed above a substrate layer without micro-trenching. The etching occurs in a process chamber during a main etch with a first process gas mixture having a fluorocarbon gas, a hydrofluorocarbon gas, and an oxygenating gas. Next, the method includes etching openings partially into the substrate without micro-trenching with a second process gas mixture during an over etch having the fluorocarbon gas, the hydrofluorocarbon gas, and the oxygenating gas.

In some embodiments, the first process gas mixture has a flow rate of the fluorocarbon gas that is greater than a flow rate of the hydrofluorocarbon gas at a pressure between approximately 0 and 20 millitorr. The second process gas mixture has a flow rate of the fluorocarbon gas that is less than a flow rate of the hydrofluorocarbon gas at a pressure between approximately 50 and 80 millitorr. Also, no source bias is applied to the process chamber during the over etch in order to prevent micro-trenching into the substrate.

Next, the method includes etching trenches in the underlying substrate (e.g., silicon) without micro-trenching at block 110. The above etching operations may be performed in-situ in one process tool. Alternatively, the above etching operations may be performed ex-situ using more than one process tool.

The following description provides details of manufacturing machines that process substrates and/or wafers to manufacture devices (e.g., electronic devices, semiconductors, substrates, liquid crystal displays, reticles, micro-electro-mechanical systems (MEMS)). Manufacturing such devices generally require dozens of manufacturing steps involving different types of manufacturing processes. For example, etching, sputtering, and chemical vapor deposition are three different types of processes, each of which is performed on different chambers or in the same chamber of a machine.

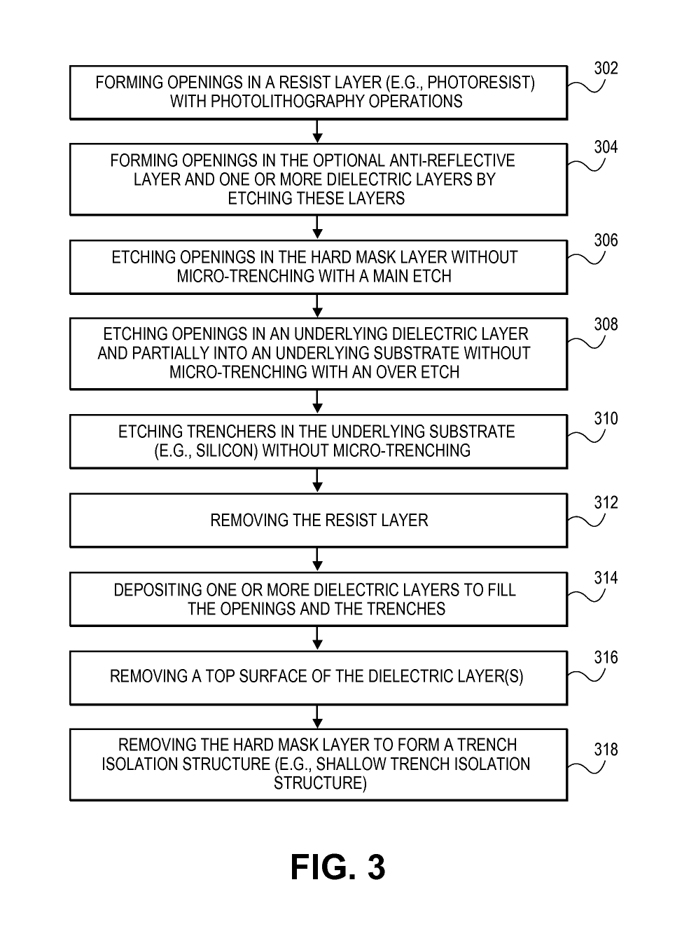

FIG. 3 illustrates one embodiment of a method for etching a masking layer disposed above a substrate to form trenches without micro-trenching in accordance with one embodiment. The method includes forming openings in a resist layer (e.g., photoresist) with photolithography operations at block 302. The resist layer may be disposed on an optional anti-reflective layer (e.g., ARC, BARC) which is disposed on one or more dielectric layers (e.g., thermal oxide, low temperature oxide, TEOS, doped oxide, an amorphous carbon layer, SiON, etc.). Next, the method includes forming openings in the optional anti-reflective layer and one or more dielectric layers by etching these layers at block 304. The dielectric layers may be disposed on a hard mask layer (e.g., nitride, polysilicon). Next, the method includes etching openings in the hard mask layer without micro-trenching with a main etch at block 306.

In one embodiment, the hard mask layer is etched with a main etch until reaching a dielectric layer in a process chamber with a low pressure (e.g., 0 to 20 mTorr) process gas mixture that includes a fluorocarbon gas (e.g., CF₄ gas), a hydrofluorocarbon gas (e.g., CHF₃ gas), and an oxygenating gas (O₂ gas). Next, the method includes etching openings in an underlying dielectric layer and partially into an underlying substrate without micro-trenching with an over etch at block 308. In one embodiment, the over etch operation in the process chamber occurs with a process gas mixture at a pressure (e.g., 50 to 80 mTorr) and includes a fluorocarbon gas (e.g., CF₄ gas), a hydrofluorocarbon gas (e.g., CHF₃ gas), and an oxygenating gas (O₂ gas).

Next, the method includes etching trenches in the underlying substrate (e.g., silicon) without micro-trenching at block 310. The above etching operations may be performed in-situ in one process tool. Alternatively, the above etching operations may be performed ex-situ using more than one process tool.

Next, the method includes removing the resist layer at block 312. Next, the method includes depositing one or more dielectric layers to fill the openings and the trenches at block 314. Next, the method includes removing a top surface of the dielectric layer(s) at block 316.

In one embodiment, the top surface of the dielectric layer(s) are removed with a chemical-mechanical planarization or chemical-mechanical polishing (CMP) process that etches partially into the hard mask layer. This process is used in semiconductor fabrication for planarizing the top surface of an in-process semiconductor wafer or other substrate. In another embodiment, other conventional semiconductor processing occurs in order to etch the dielectric layer(s) such as a blanket unmasked plasma etch or a masked plasma etch or a combination of conventional semiconductor processing. Next, the method includes removing the hard mask layer to form a trench isolation structure (e.g., shallow trench isolation structure) at block 318.

The operations of exemplary methods described in the present invention can be performed in a different order, sequence, and/or have more or less operations than described. For example, in certain embodiments, the structure is formed without removing the hard mask layer. In another embodiment, a deep trench etch is performed.

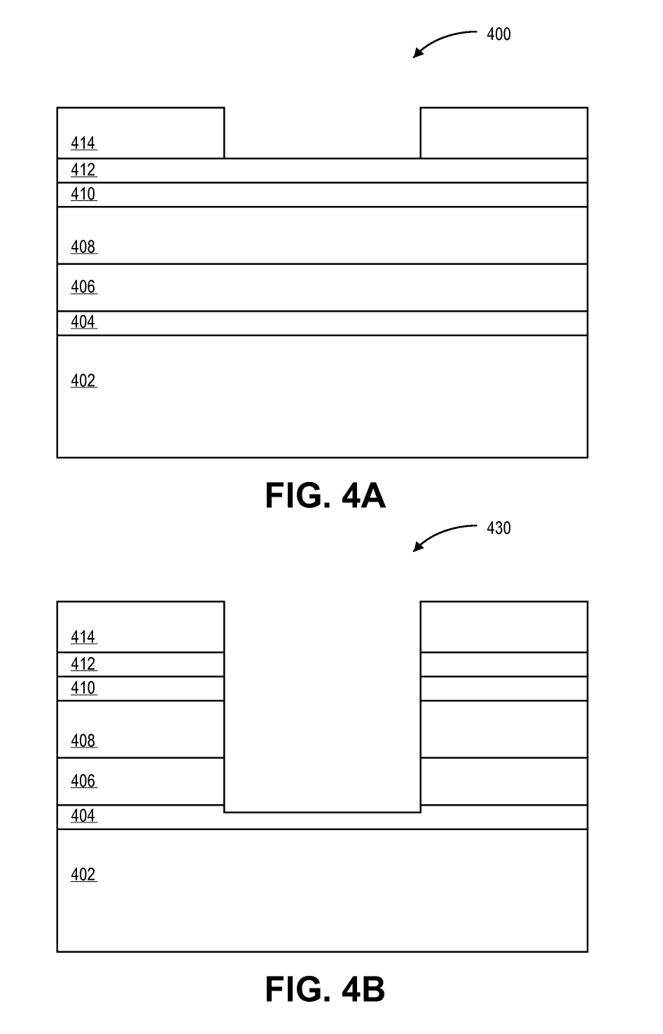

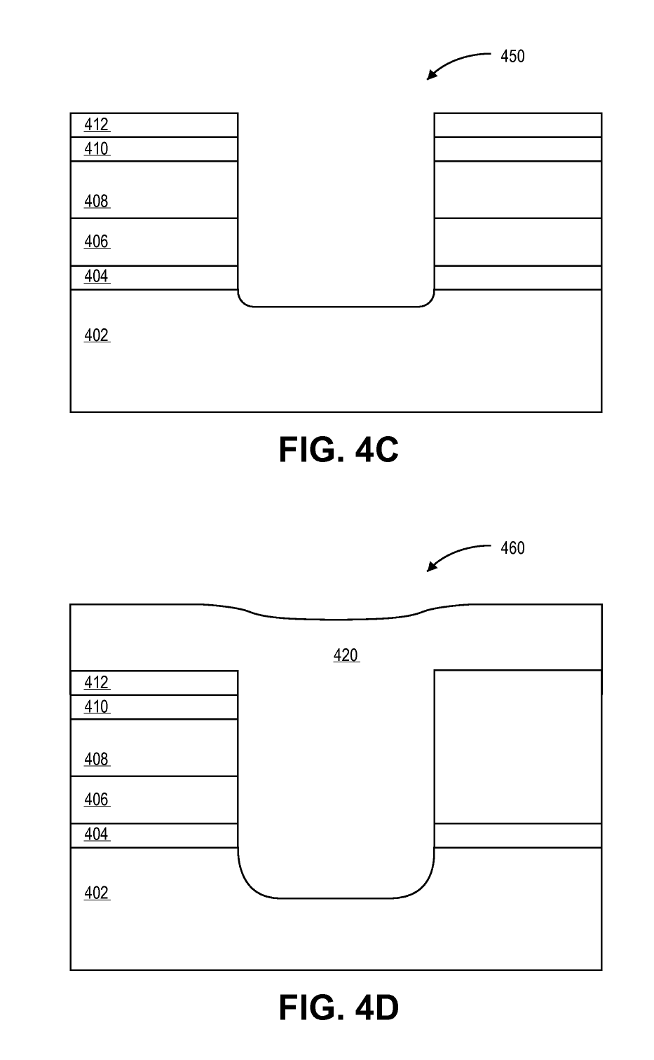

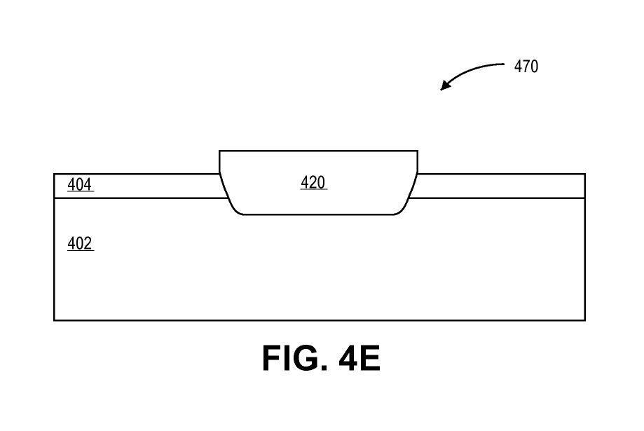

FIG. 4A illustrates a cross-sectional view of a structure fabricated to form trenches without micro-trenching in accordance with one embodiment. The structure 400 includes a substrate (e.g., silicon) 402, a dielectric layer 404 (e.g., thermal oxide, low temperature oxide, TEOS, doped oxide, etc), a hard mask layer 406 (e.g., nitride, polysilicon), an amorphous carbon layer 408, a dielectric layer 410 (e.g., SiON, low temperature oxide, organic layer, TEOS), an optional anti-reflective coating (ARC) layer 412 to minimize the reflectance of underlying layers, and a resist layer 414. The dielectric layer 404 may have a thickness less than 200 nanometers (nm). The hard mask layer 406 may have a thickness of 70 to 150 nm. The resist layer 414 may be a photosensitive photoresist layer that is blanket coated or deposited across the structure, masked, exposed to a light source, and developed to form trench openings in accordance with standard photolithography operations.

FIG. 4B illustrates a cross-sectional view of a structure fabricated to form trenches without micro-trenching in accordance with another embodiment.

The structure 430 of FIG. 4B illustrates the structure 400 of FIG. 4A after etching the layers 404, 406, 408, 410, and 412. In one embodiment, the hard mask layer 406 is etched with a main etch until reaching the dielectric layer 404 in a process chamber with a low pressure (e.g., 0 to 20 mTorr) process gas mixture that includes a fluorocarbon gas (e.g., CF₄ gas), a hydrofluorocarbon gas (e.g., CHF₃ gas), and an oxygenating gas (O₂ gas). For example, the fluorocarbon gas may include at least one fluorocarbon containing gas such as but not limited to C₄F₆ gas, C₄F₈ gas, CF₄ gas, and CHF₃ gas.

FIG. 4C illustrates a cross-sectional view of a structure fabricated to form trenches without micro-trenching in accordance with another embodiment. The structure 450 of FIG. 4C illustrates the structure 430 of FIG. 4B after performing an over etch operation that etches the layers 406, 404, and partially into layer 402 (e.g., 50 to 100 Angstroms). In one embodiment, the over etch operation in a process chamber occurs with a process gas mixture at a pressure (e.g., 50 to 80 mTorr) and includes a fluorocarbon gas (e.g., CF₄ gas), a hydrofluorocarbon gas (e.g., CHF₃ gas), and an oxygenating gas (O₂ gas). For example, the fluorocarbon gas may include at least one fluorocarbon containing gas such as but not limited to C₄F₆ gas, C₄F₈ gas, CF₄ gas, and CHF₃ gas.

In a specific embodiment, the main etch and over etch include the following process parameters:

| Step | Press | Ws | Wb | O2 | CF4 | CHF3 | DC | TGN | Temp (i/o) | Cathode | Time |
|---|---|---|---|---|---|---|---|---|---|---|---|
| Nitride | 5 | 500 | 200 | 4 | 260 | 120 | 19 | S2 | 20, 20 | 0 | ept (38.8″) |
| Nit OE | 60 | 0 | 600 | 4 | 100 | 230 | | O1C2 | 20, 20 | 0 | 30″ |

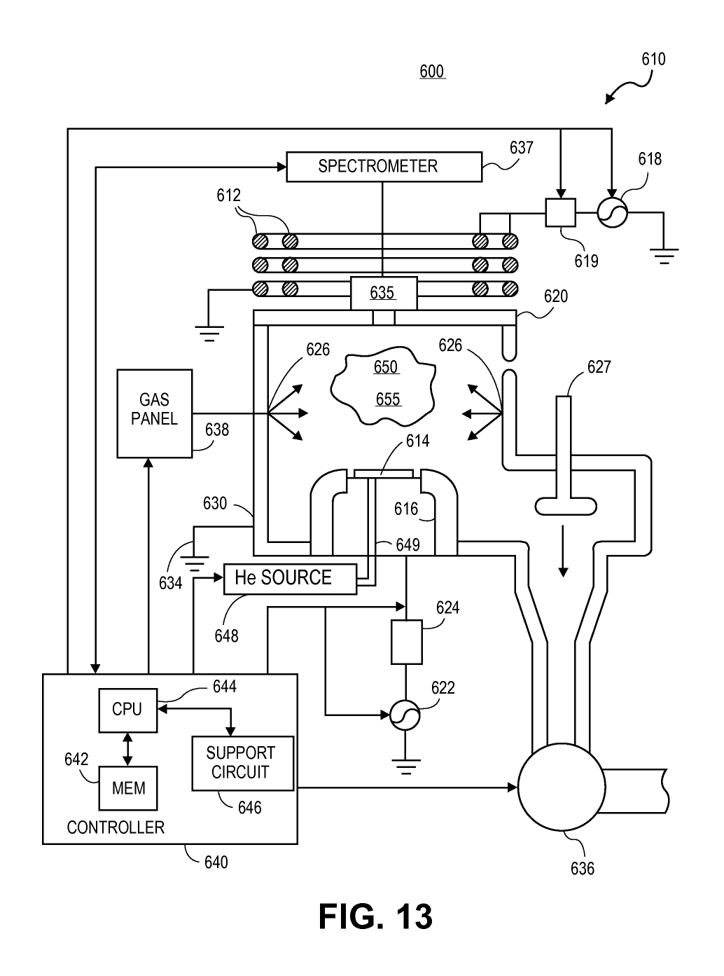

In the specific embodiment, the source power is set to zero, in contrast to the main etch, to minimize or eliminate micro-trenching during the over etch. The over etch has a selectivity of approximately 10:1 between a nitride or oxide layer and a silicon layer with an etch rate of approximately 1100 Angstroms/minute. A high pressure of approximately 60 mTorr reduces the mean free path of ions leading to more collisions and less micro-trenching in comparison to etching at lower pressures. The etching occurs in a plasma etch chamber, like Applied Materials' DPS AdvantEdge described in conjunction with FIG. 13.

In some embodiments, the over etch has a source power (Ws) with a range of 0 to 600 Watts (W), a bias power (Wb) with a range of 300 to 700 W, an oxygen gas flow of 4 to 25 sccm, a CF₄ gas flow of 50-150 sccm, a CHF₃ gas flow of 200 to 300 sccm, and a process time of 20 to 30 seconds. The source power controls ion density and the bias power controls ion energy. A divider cap (DC) adjusts a current ratio for the source power to improve etch uniformity across a substrate. A tunable gas nozzle (TGN) tunes the neutral density in the process chamber.

The process gas mixture can also be used with inert gases, such as helium or xenon gas. The process gas mixture can be used to etch various dielectric layers and underlying substrates to form trenches, or other structures. In particular, the process gas mixture can be used to form silicon trenches that are part of a shallow trench isolation structure.

FIG. 4D illustrates a cross-sectional view of an isolation structure fabricated to form trenches without micro-trenching in accordance with another embodiment. The structure 460 of FIG. 4D illustrates the structure 450 of FIG. 4C after performing a substrate etch operation that etches the layer 402 to form a trench and then deposits one or more dielectric layers 420 to fill the trench.

FIG. 4E illustrates a cross-sectional view of an isolation structure fabricated to form trenches without micro-trenching in accordance with another embodiment. The structure 470 of FIG. 4E illustrates the structure 460 of FIG. 4D after removing a top surface of the dielectric layer(s) and optionally removing the layer 406 to form the isolation structure 470 for isolating devices.

In one embodiment, the top surface of the dielectric layer(s) are removed with a chemical-mechanical planarization or chemical-mechanical polishing (CMP) process that etches partially into the hard mask layer 406. This process is used in semiconductor fabrication for planarizing the top surface of an in-process semiconductor wafer or other substrate. In another embodiment, other conventional semiconductor processing occurs in order to etch the dielectric layer(s) such as a blanket unmasked plasma etch or a masked plasma etch or a combination of conventional semiconductor processing.

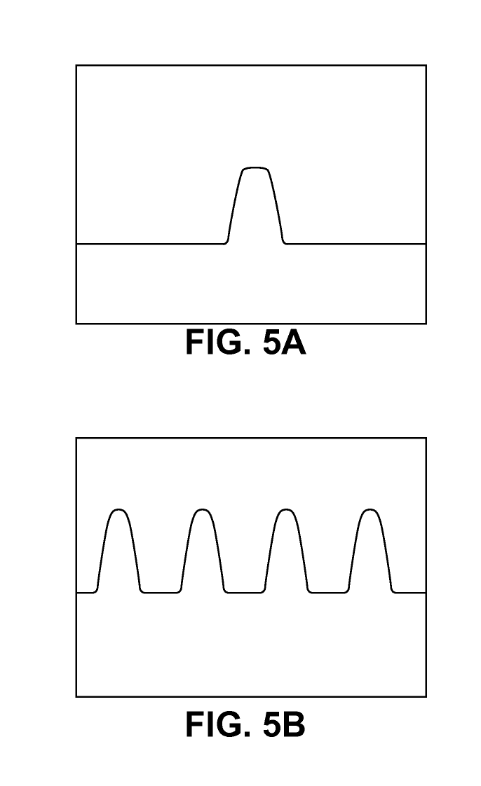

FIGS. 5A and 5B illustrate cross-sectional views of a structure fabricated to form trenches without micro-trenching in accordance with one embodiment. FIG. 5A illustrates an isolated feature and 5B illustrates a dense feature with neither having micro-trenching. The hard masking layer 406, which may be a nitride layer, is etched with a main etch and over etch as discussed above.

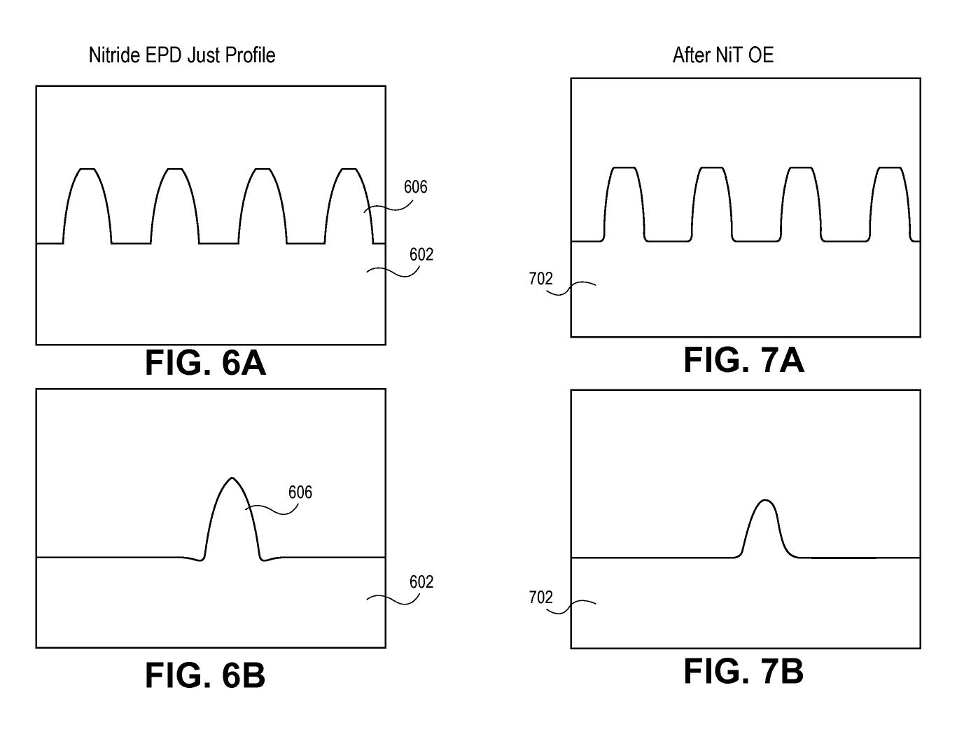

FIGS. 6A and 6B illustrate cross-sectional views of a structure fabricated to form trenches without micro-trenching in accordance with one embodiment. FIG. 6B illustrates an isolated feature and 6A illustrates a dense feature with a small amount of micro-trenching occurring during the main etch. The hard masking layer 606, which may be a nitride layer, is etched with the main etch and over etch in accordance with one embodiment as follows.

Test 9

| Step | Press | Ws | Wb | O2 | He | CF4 | CHF3 | He—O2 | HBr | DC | Flow | Temp (i/o) | Cathode | Time |
|---|---|---|---|---|---|---|---|---|---|---|---|---|---|---|
| Nitride | 5 | 500 | 200 | 4 | | 260 | 120 | | | 19 | S2 | 20, 20 | 0 | ept (37.3″) |
| OE | 60 | 0 | 600 | 4 | | 100 | 230 | | | 19 | S2 | 20, 20 | 0 | 30″ |

The over etch rounds the corners of the trench and removes any micro-trenching as illustrated in FIGS. 7A and 7B. Subsequent etching of the substrate layer 702 will also not have micro-trenching.

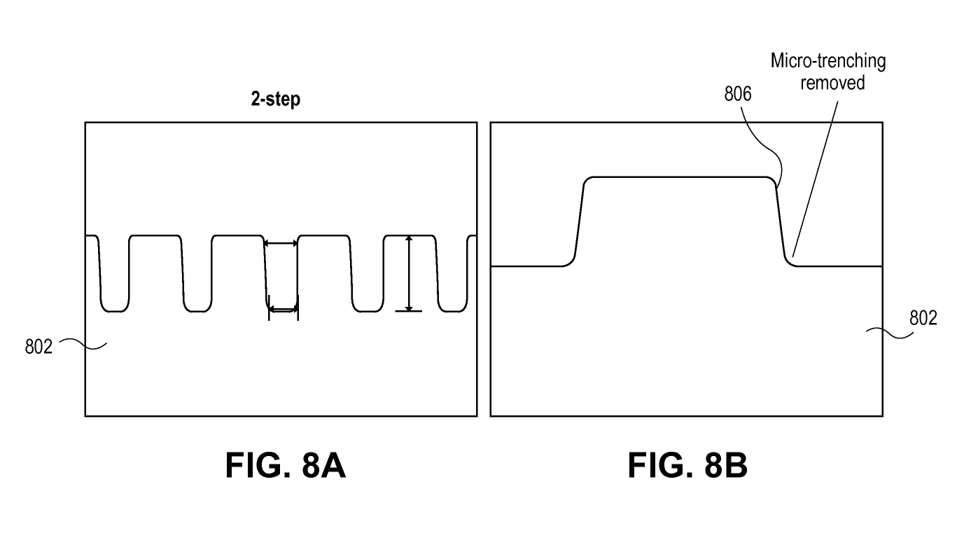

FIGS. 8A and 8B illustrate cross-sectional views of a structure fabricated to form trenches without micro-trenching in accordance with another embodiment. FIG. 8A illustrates an isolated feature and FIG. 8B illustrates a dense feature. The hard masking layer 806, which may be a nitride layer, is etched with the main etch and over etch in accordance with one embodiment as follows.

| Step | Press | Ws | Wb | O2 | CF4 | CHF3 | DC | TGN | Temp (i/o) | Cathode | Time |
|---|---|---|---|---|---|---|---|---|---|---|---|
| Nitride | 5 | 500 | 200 | 4 | 260 | 120 | 19 | S2 | 20, 20 | 0 | ept (38.8″) |
| Nit OE | 60 | 0 | 600 | 4 | 100 | 230 | | O1C2 | 20, 20 | 0 | 30″ |

The over etch rounds the corners of the trench and removes any micro-trenching as illustrated in FIGS. 8A and 8B. Subsequent etching of the substrate layer 802 will also not have micro-trenching.

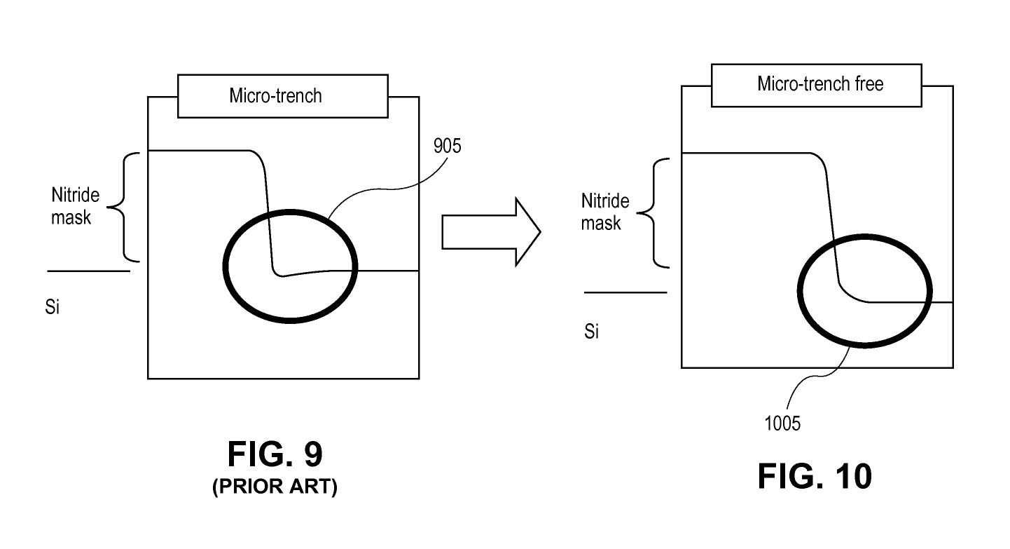

FIG. 9 illustrates a cross-sectional view of a structure fabricated to form trenches with micro-trenching in accordance with a conventional approach. The micro-trenching 905 occurs at edges of features along a sidewall of the nitride masking and extends into the silicon substrate.

FIG. 10 illustrates a cross-sectional view of a structure fabricated to form trenches without micro-trenching in accordance with another embodiment. A region 1005 that transitions from a nitride mask to a silicon substrate has no micro-trenching. Rather, the region 1005 extends smoothly from the nitride mask to the silicon substrate. A subsequent STI etch into the silicon substrate will also show no micro-trenching, thus, resulting in improved isolation and device performance.

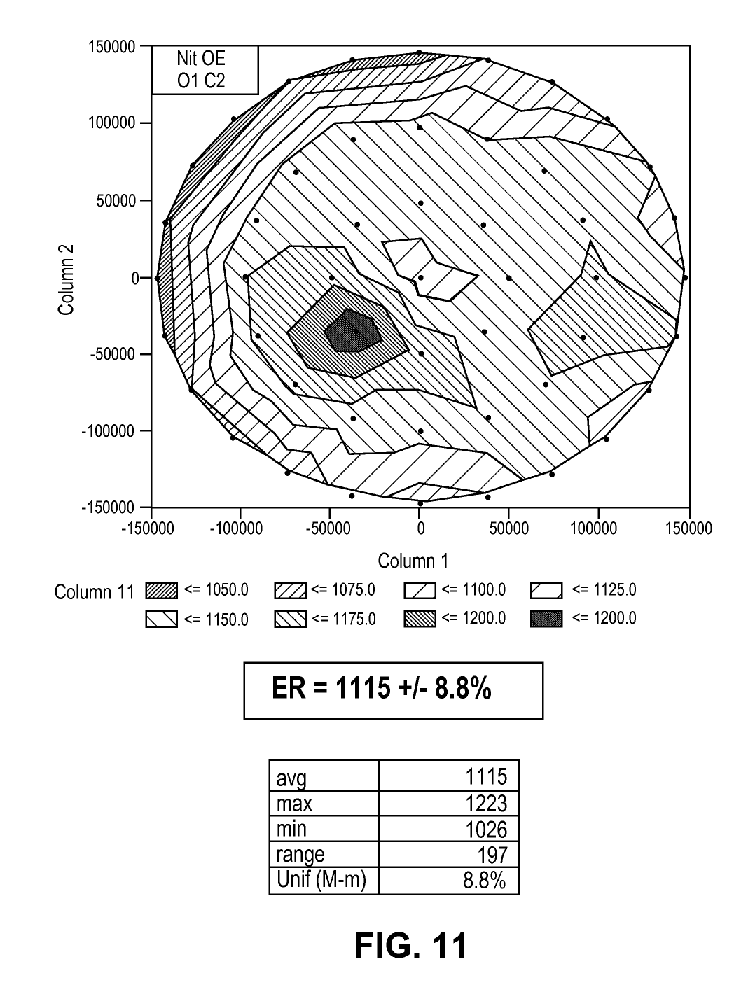

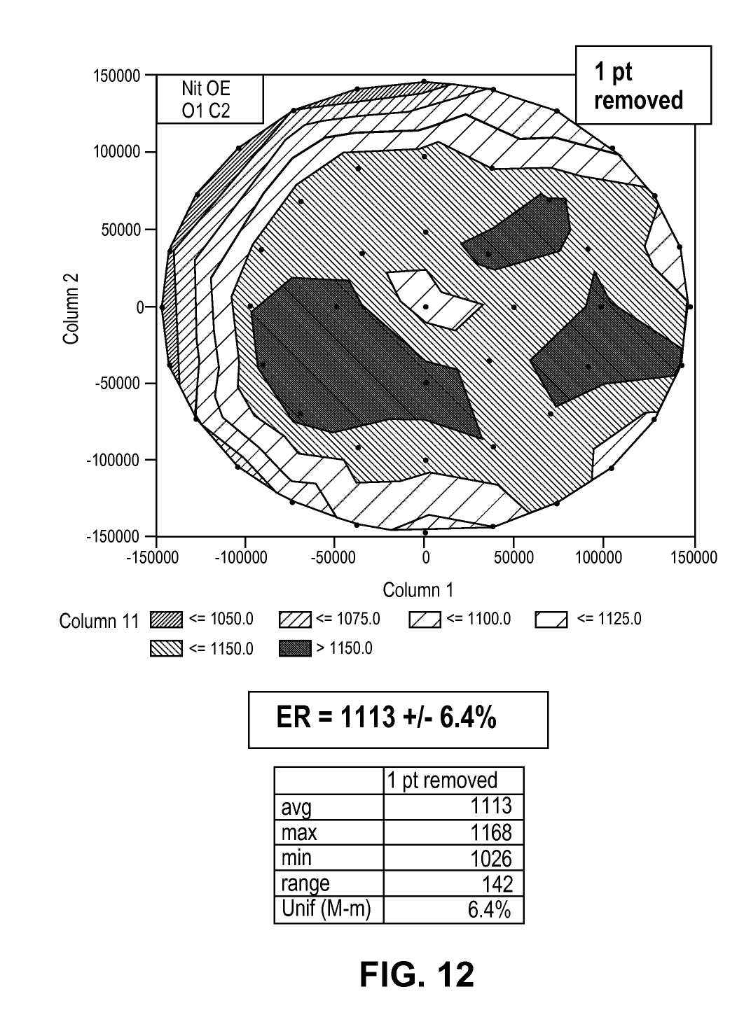

FIGS. 11 and 12 illustrate uniformity maps of a nitride layer after the nitride layer is etched in accordance with one embodiment. The uniformity maps illustrates the uniformity of a blanket nitride layer that is etched with the nitride over etch operation. In one embodiment, the over etch operation includes the following parameters.

60 mT/0 Ws/600 Wb/4O2/100CF4/230CHF3/TGN X/20, 20, 0/30″

A tunable gas nozzle (TGN) tunes the neutral density in the process chamber. In this embodiment, the TGN is set to an edge of the wafer only flow (O1 C2). An outer edge of data points are removed for the uniformity map illustrated in FIG. 12.

The structures discussed above can be fabricating with the apparatus 1300 described herein which is suitable for processing substrates such as semiconductor substrates 202, and may be adapted by those of ordinary skill to process other substrates such as flat panel displays, polymer panels or other electrical circuit receiving structures. Thus, the apparatus 500 should not be used to limit the scope of the invention, nor its equivalents, to the exemplary embodiments provided herein.

An embodiment of an apparatus 600 suitable for processing substrates according to the processes described herein, is shown in FIG. 13. FIG. 13 depicts a schematic diagram of a exemplary Decoupled Plasma Source DPS etch reactor 600 that may be used to practice portions of the invention. The DPS reactor is generally used as a processing module of the CENTURA® processing system available from Applied Materials, Inc. of Santa Clara, Calif.

The reactor 600 comprises a process chamber 610 having a wafer support pedestal 616 within a conductive body (wall) 630, a beam-forming optics 635, a spectrometer 637, and a controller 640. The beam-forming optics 635 collect the reflectance from the substrate and the collected signals are sent to the spectrometer 637. The spectrometer 637 is connected to the controller 640. The substrate reflectance signals are analyzed by the spectrometer 637 and a processor 644 in the controller 644. The chamber could have be supplied with an optional external broadband light source (not shown) to provide light for substrate reflectance measurement. The chamber 610 is supplied with a substantially flat dielectric ceiling 620. Other modifications of the chamber 610 may have other types of ceilings, e.g., a dome-shaped ceiling. Above the ceiling 620 is disposed an antenna comprising at least one inductive coil element 612 (two co-axial elements 612 are shown). The inductive coil element 612 is coupled, through a first matching network 619, to a plasma power source 618. The plasma source 618 typically is capable of producing up to 3000 W at a tunable frequency in a range from 50 kHz to 13.56 MHz.

The support pedestal (cathode) 616 is coupled, through a second matching network 624, to a biasing power source 622. The biasing power source 622 generally is capable of producing up to 10 kW at a frequency of approximately 13.56 MHz. The biasing power may be either continuous or pulsed power. In other embodiments, the biasing power source 622 may be a DC or pulsed DC source.

A controller 640 comprises a central processing unit (CPU) 644, a memory 642, and support circuits 646 for the CPU 644 and facilitates control of the components of the chamber 610 and, as such, of the etch process, as discussed.

In operation, a substrate 614 is placed on the pedestal 616 and process gases are supplied from a gas panel 638 through entry ports 626 to form a gaseous mixture 650. The gaseous mixture 650 is ignited into a plasma 655 in the chamber 610 by applying power from the plasma source 618 and biasing source power 622 to the inductive coil element 612 and the cathode 616, respectively. The pressure within the interior of the chamber 610 is controlled using a throttle valve 627 and a vacuum pump 636. Typically, the chamber wall 630 is coupled to an electrical ground 634. The temperature of the wall 630 is controlled using liquid-containing conduits (not shown) that run through the wall 630.

The temperature of the substrate 614 is controlled by stabilizing a temperature of the support pedestal 616. In one embodiment, helium gas from a gas source 648 is provided via a gas conduit 649 to channels (not shown) formed in the pedestal surface under the substrate 614. The helium gas is used to facilitate heat transfer between the pedestal 616 and the substrate 614. During processing, the pedestal 616 may be heated by a resistive heater (not shown) within the pedestal to a steady state temperature and then the helium gas facilitates uniform heating of the substrate 614. Using such thermal control, the substrate 614 is maintained at a temperature between about 20 to 350 degrees Celsius.

Those skilled in the art will understand that other etch chambers may be used to practice the invention, including chambers with remote plasma sources, electron cyclotron resonance (ECR) plasma chambers, and the like.

To facilitate control of the process chamber 610 as described above, the controller 640 may be one of any form of general-purpose computer processor that can be used in an industrial setting for controlling various chambers and sub-processors. The memory 642, or computer-readable medium, of the CPU 644 may be one or more of readily available memory such as random access memory (RAM), read only memory (ROM), floppy disk, hard disk, or any other form of digital storage, local or remote. The support circuits 646 are coupled to the CPU 644 for supporting the processor in a conventional manner. These circuits include cache, power supplies, clock circuits, input/output circuitry and subsystems, and the like. The inventive method is generally stored in the memory 642 as a software routine. The software routine may also be stored and/or executed by a second CPU (not shown) that is remotely located from the hardware being controlled by the CPU 644.

In one embodiment, the controller 640 includes computer program instructions that are readable by the computer and may be stored in the memory, for example on the non-removable storage medium or on the removable storage medium. The computer program instructions generally includes process control software including program code including instructions to operate the chamber and its components, process monitoring software to monitor the processes being performed in the chamber, safety systems software, and other control software.

In a specific embodiment for a nitride etch, the controller 640 includes program code instructions to operate the gas distributor to introduce into the chamber a process gas mixture including the following:

Test 9

| Step | Press | Ws | Wb | O2 | He | CF4 | CHF3 | He—O2 | HBr | DC | Flow | Temp (i/o) | Cathode | Time |
|---|---|---|---|---|---|---|---|---|---|---|---|---|---|---|
| Nitride | 5 | 500 | 200 | 4 | | 260 | 120 | | | 19 | S2 | 20, 20 | 0 | ept (37.3″) |
| OE | 60 | 0 | 600 | 4 | | 100 | 230 | | | 19 | S2 | 20, 20 | 0 | 30″ |

A nitride layer, is etched with the main etch and over etch in accordance with one embodiment in a plasma etch chamber, like Applied Materials' decoupled plasma source (DPS) etcher described in conjunction with FIG. 13.

One embodiment, the substrate processing apparatus 1300 includes a dual zone heated electrostatic chuck (ESC), an improved temperature ramping (≧2 degrees C./sec), an improved temperature uniformity (R≦4 degrees), a TC/AC Box, 3400 liter/second turbo pump with 320 Spool (BOC), and a VAT TGV ISO320 w/Onboard Control. A cathode section includes has a high current capacity, an improved RF grounding, an improved heater wire routing, an improved wafer lift, fast response optical probes, an improved RF AC Filterbox.

The substrate processing apparatus 1300, in an embodiment, is an Applied Materials' DPS II AdvantEdge etcher that can be used with feature sizes of 55 nanometers and below with the following features and benefits.

| AdvantEdge Features | Benefit |
|---|---|
| G3 Fast Ramp Chuck | 50% improved temperature uniformity |
| | Step-to-step temperature ramp |
| | 2x larger temperature gradient |
| High Conductance Pump | Improved profile and etch rate microloading |
| System | |
| Optimized Lid Heater | Etch Rate Uniformity improved by 30% |
| | at medium pressures |

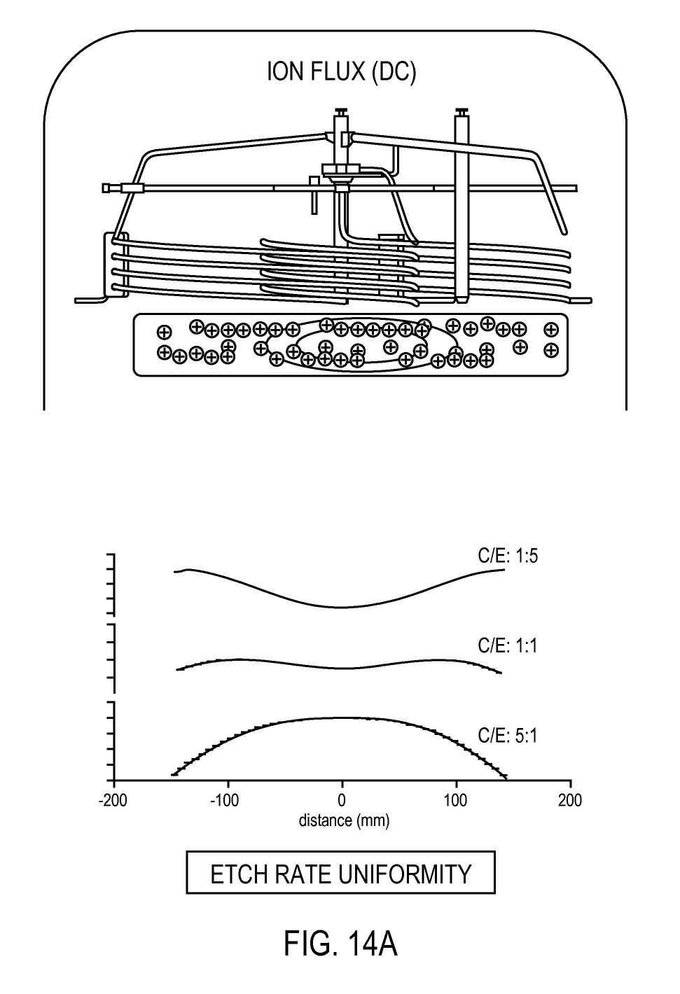

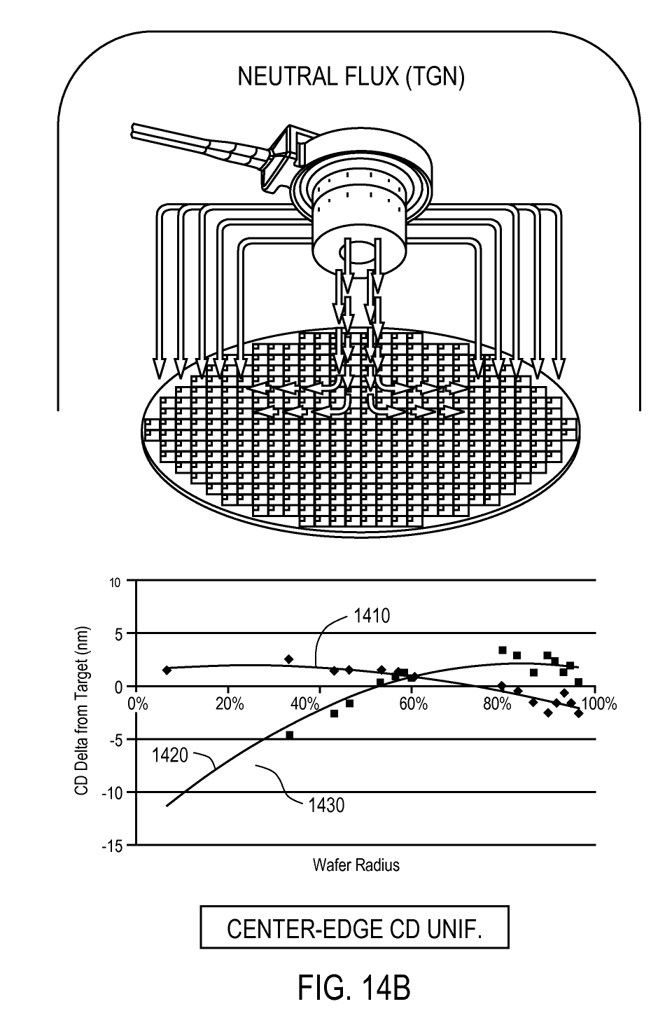

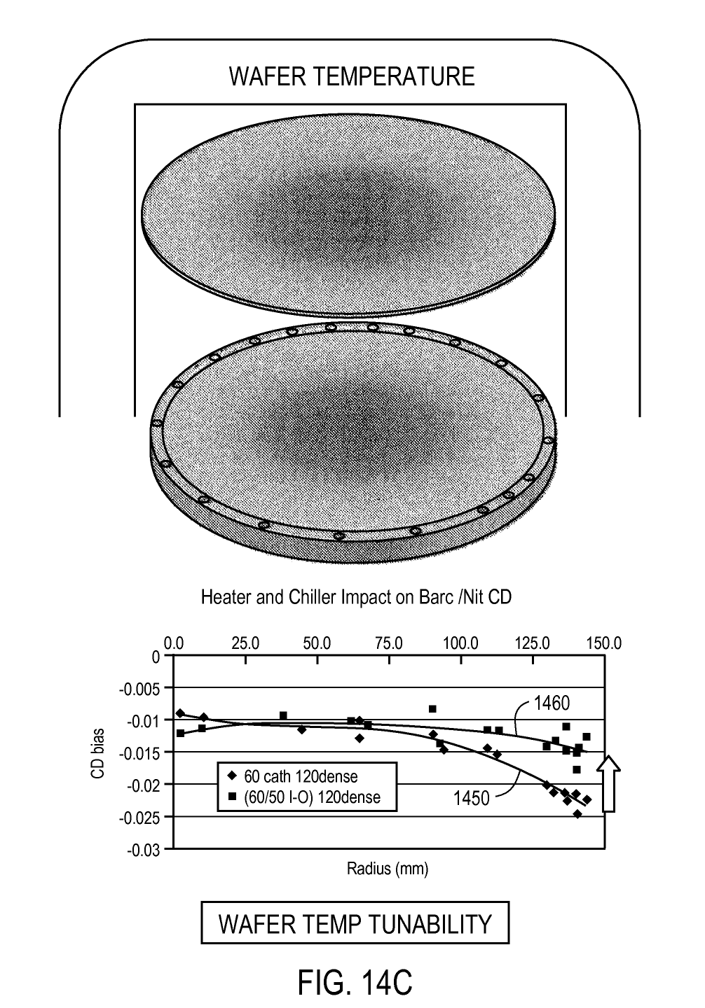

FIG. 14A illustrates a center to edge etch rate uniformity diagram for the substrate processing tool in accordance with one embodiment. In this diagram, ion flux is altered from center to edge in a ratio of 1:5, 1:1, and 5:1.

FIG. 14B illustrates a center to edge CD uniformity diagram for the substrate processing tool in accordance with one embodiment. In this diagram, neutral flux is varied between inner and outer regions of a wafer with a tunable gas nozzle (TGN). Line 1410 represents an inner region having a lower flux than an outer region, line 1420 represents an inner region having an approximately equal flux compared to an outer region, and line 1430 represents an inner region having a higher flux than an outer region.

FIG. 14C illustrates a wafer temperature tunability diagram for the substrate processing tool in accordance with one embodiment. In this diagram, wafer temperature is varied between inner and outer regions of a wafer with a heater and chiller, which affects CD bias of the barc/nitride CD across the wafer (0 to 150 mm radius). Line 1450 represents a 60 degree temperature setting across inner and outer regions of a wafer and a cathode dense setting of 120. Line 1460 represents a 60 degree temperature setting across an inner region and a 50 degree setting across an outer region of a wafer with a cathode dense setting of 120.

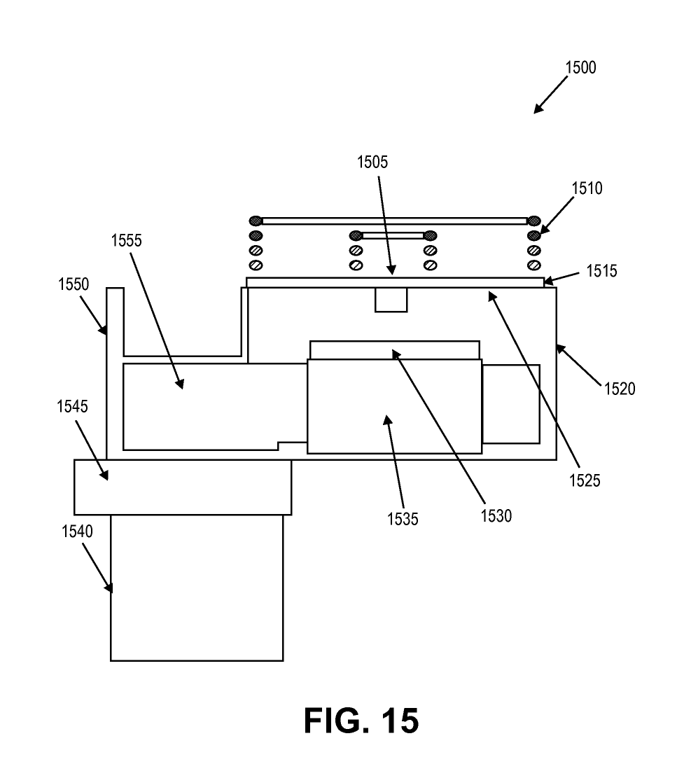

FIG. 15 is a substrate processing tool in accordance with another embodiment. The substrate processing tool 1500 includes a tunable gas nozzle 1505 that provides a continuous tuning of neutral density, a tunable source 1510 that controls a tunable plasma uniformity, a non sputtering source, and produces higher productivity. The tool 1500 also includes a resistively heated lid 1515 for temperature uniformity, a removable slit valve door 1520 having a short wet clean time, an upper liner 1525 that is symmetrical with a short wet clean time, a dual heater ceramic ESC 1530 that provides uniformity control and wafer less dry cleans,

The substrate processing tool 1500 also has a bias pulsing capability 1535 for additional process flexibility, a 3400 L/s Turbo pump 1540, a throttling gate valve 1545 to provide a high conductance and pressure control, a chamber body 1550 with a pump plenum and liner temperature control, a lower liner 1555 having short wet clean time. The tool 1500 combines a rotationally symmetrical design with center-to-edge tuning features.

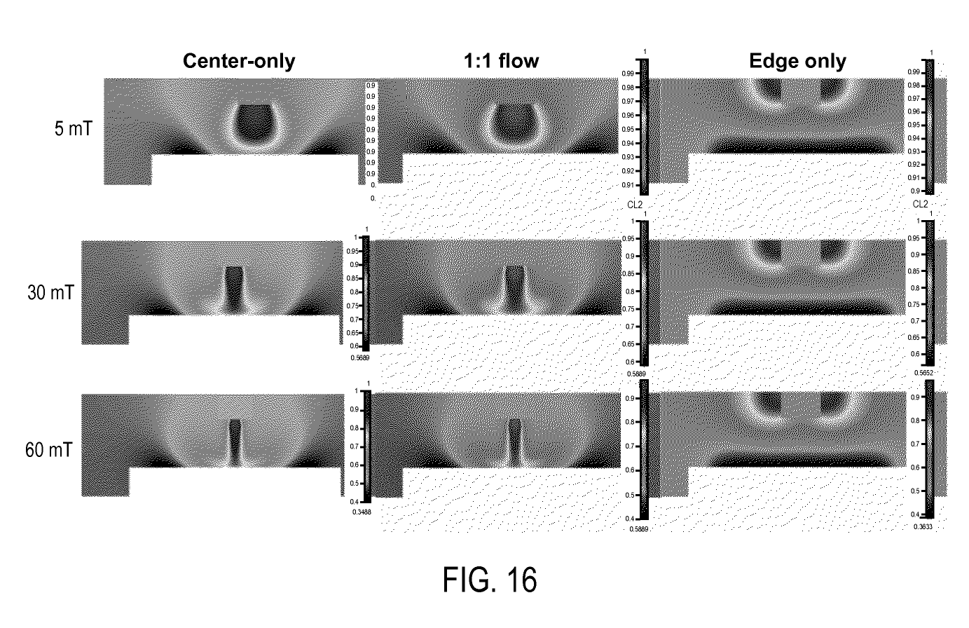

FIG. 16 illustrates flow diagrams for a reactant mass fraction control of the substrate processing tool in accordance with one embodiment. A TGN varies a flow setting (e.g., center only, 1:1 between center and edge, and edge only) across a wafer in order to change reactant concentration and uniformity across a wafer for various pressures (e.g., 5 mT, 30 mT, and 60 mT) with a 300 sccm total flow. A higher reactant concentration t a wafer center compared to edge is achieved using the TGN with a center only flow setting. A more uniform reactant concentration is achieved with the edge only flow setting.

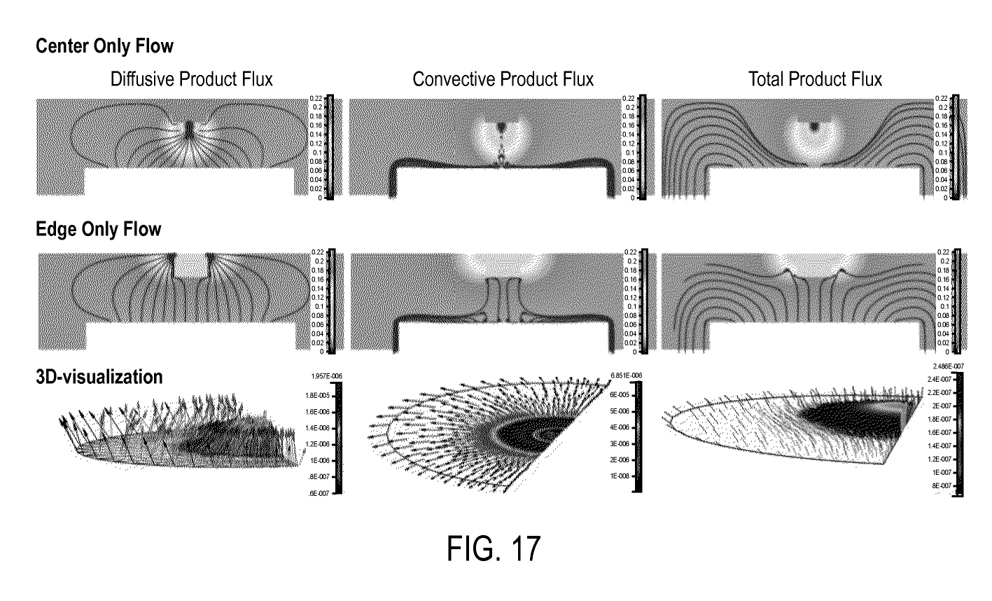

FIG. 17 illustrates product flux diagrams for center versus edge flow of the substrate processing tool in accordance with one embodiment. A TGN varies a flow setting (e.g., center only, 1:1 between center and edge, and edge only) across a wafer in order to control etch byproduct distribution at a pressure of 5 mT and a 100 sccm total flow. Etch byproducts are pumped out effectively from the center of a wafer with a center only flow setting. For an edge only flow setting, diffusion dominates and etch byproducts accumulate at the center of the reactor.

In the following description, numerous details are set forth. It will be apparent, however, to one skilled in the art, that the present invention may be practiced without these specific details. In some instances, well-known structures and devices are shown in block diagram form, rather than in detail, in order to avoid obscuring the present invention. It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method, comprising:
etching openings in a nitride layer disposed above a substrate layer without micro-trenching in a process chamber with a first process gas mixture having a fluorocarbon gas, a hydrofluorocarbon gas, and an oxygenating gas; and
etching openings partially into the substrate without micro-trenching with a second process gas mixture having the fluorocarbon gas, the hydrofluorocarbon gas, and the oxygenating gas.

2. The method of claim 1, wherein the first process gas mixture has a flow rate of fluorocarbon gas that is greater than a flow rate of hydrofluorocarbon gas at a pressure between approximately 0 and 20 millitorr.

3. The method of claim 1, wherein the second process gas mixture has a flow rate of fluorocarbon gas that is less than a flow rate of hydrofluorocarbon gas at a pressure between approximately 50 and 80 millitorr.
